(19) United States
(12) Patent Application Publication
(10) Pub. No.: US 2013/0140682 A1
(43) Pub. Date: Jun. 6, 2013

(54) BURIED WORD LINE AND METHOD FOR FORMING BURIED WORD LINE IN SEMICONDUCTOR DEVICE

(71) Applicants: Chi-Wen Huang, Taoyuan County (TW); Kuo-Hui Su, Taipei City (TW)

(72) Inventors: Chi-Wen Huang, Taoyuan County (TW); Kuo-Hui Su, Taipei City (TW)

(21) Appl. No.: 13/309,523

(22) Filed: Dec. 1, 2011

(51) Int. Cl. H01L 29/06; H01L 21/336

(52) U.S. Cl. 257/622; 438/586; 257/E21.409; 257/E29.005

(57) ABSTRACT

A buried word line includes a substrate having thereon a recessed trench, an insulating layer on a bottom surface and a sidewall of the recessed trench, and a lining layer in the recessed trench. The lining layer has a cleaned surface that is cleaned by a cleaning solution comprising HF or H3PO4. A tungsten layer is selectively deposited on the cleaned surface of the lining layer.

### BACKGROUND OF THE INVENTION

1. Field of the Invention

The present invention relates generally to the field of semiconductor fabrication and, in particularly, to a method for forming a buried word line in a DRAM device.

2. Description of the Prior Art

In the fabrication of the advanced DRAM devices, it is normal to form a buried word line in order to increase the integration degree of a transistor in a cell and to improve the device property. To reduce the sheet resistance, the buried word line is typically a bi-layer comprised of a titanium nitride (TiN) layer and a tungsten (W) layer.

FIG. 1 is a flowchart illustrating the steps for forming a buried word line in a DRAM device according to the prior art. As shown in FIG. 1, in Step 10, a semiconductor substrate or a substrate is provided. At least one recessed trench is formed at the surface of the substrate. In Step 11, a blanket TiN layer is deposited over the substrate and over the interior surface of the recessed trench. In Step 12, after the deposition of the blanket TiN layer, a blanket W layer is then deposited on the TiN layer to fill the recessed trench. In Step 13, an in-situ dry etching process is then carried out to etch away an upper portion of the TiN/W bi-layer from the recessed trench, thereby forming a buried word line.

However, the above-described prior art method has shortcomings. For example, the blanket deposition of the TiN/W bi-layer prior to the in-situ dry etching process induces a large stress to the substrate, which may adversely affect the yield of the fabrication process. Line bending or deformation may occur due to the stress. Further, the above-described prior art method may cause a gap-filling problem as the dimension of the recessed trench shrinks.

### SUMMARY OF THE INVENTION

It is one objective of the invention to provide an improved method for forming a buried word line in a DRAM device in order to overcome the above-described prior art problems or shortcomings.

In one aspect of the invention, a method for forming a buried word line includes providing a substrate having thereon a recessed trench; blanket depositing a lining layer over the substrate and in the recessed trench; removing an upper portion of the lining layer from the recessed trench, thereby exposing a sidewall of the recessed trench; and selectively depositing a tungsten layer on the lining layer.

From another aspect of the invention, a buried word line includes a substrate having thereon a recessed trench, an insulating layer on a bottom surface and a sidewall of the recessed trench, and a lining layer in the recessed trench. The lining layer has a cleaned surface that is cleaned by a cleaning solution comprising HF or H3PO4. A tungsten layer is selectively deposited on the cleaned surface of the lining layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a flowchart illustrating the steps for forming a buried word line in a DRAM device according to the prior art; and

FIGS. 2A-2C are diagrams showing a method for forming a buried word line in a DRAM device according to one embodiment of this invention.

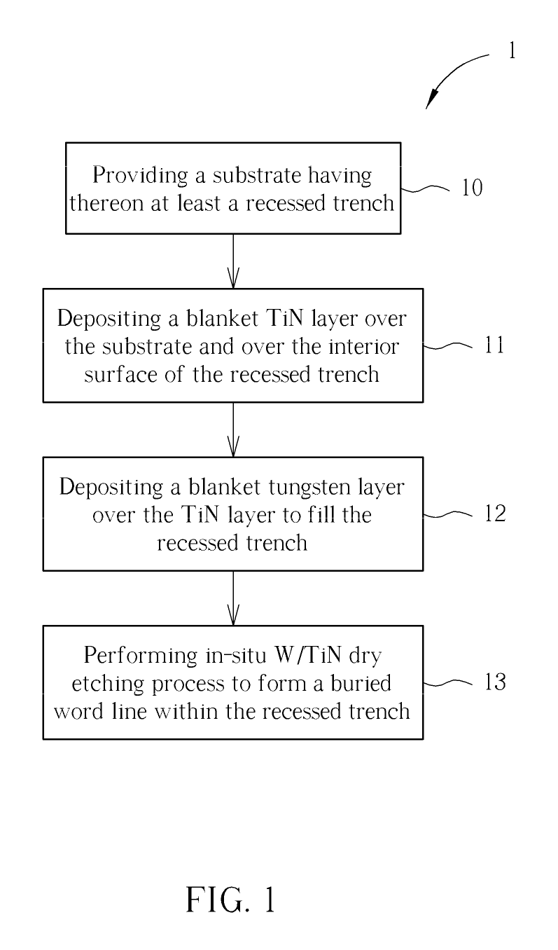

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

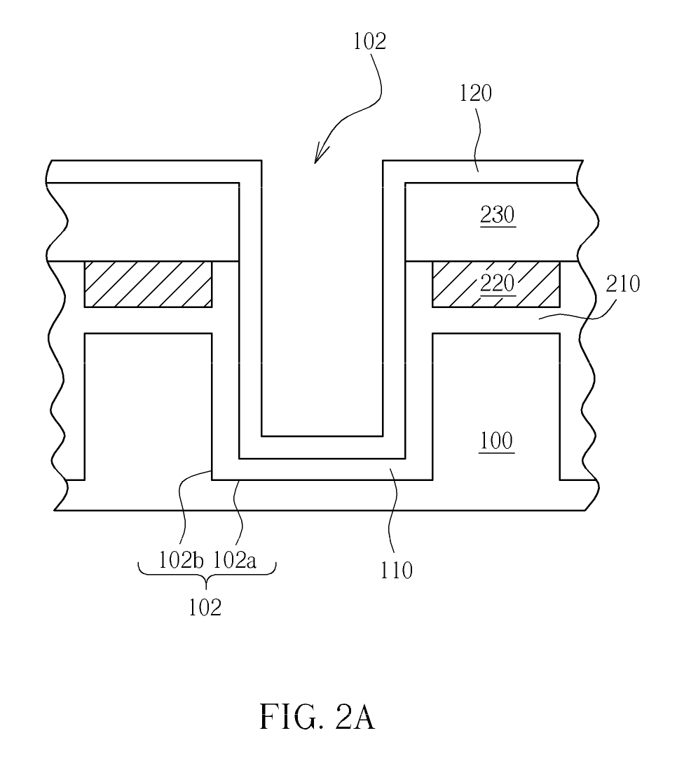

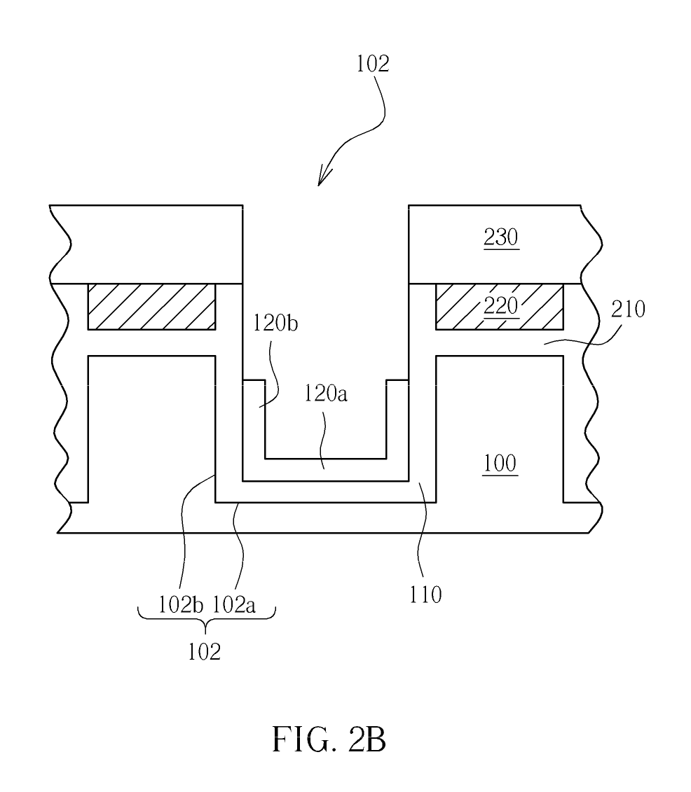

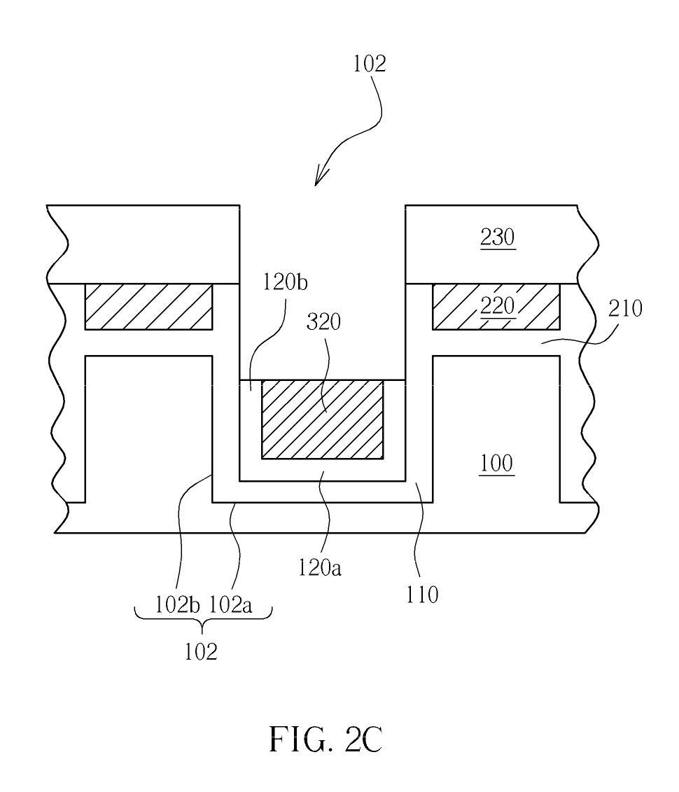

Referring to FIGS. 2A-2C, an exemplary method for forming a buried word line in a DRAM device according to one embodiment of this invention is provided. As shown in FIG. 2A, a semiconductor substrate 100 such as a silicon substrate or an epitaxial semiconductor substrate is provided. At least one recessed trench 102 is formed at the surface of the semiconductor substrate 100. The recessed trench 102 may have a bottom surface 102a and a sidewall 102b. An insulating layer 110, such as a silicon oxide layer, may be formed on the bottom surface 102a and the sidewalls 102b. On the main surface of the semiconductor substrate 100, a pad layer 230, such as a silicon nitride layer, a silicon oxide layer, or a combination thereof, may be provided. A peripheral gate structure 210 and 220 may be formed between the pad layer 230 and the semiconductor substrate 100.

A blanket chemical vapor deposition (CVD) process is then performed to deposit a conformal lining layer 120 over the semiconductor substrate 100. According to the embodiment of this invention, the lining layer 120 may comprise titanium, titanium nitride, tantalum, tantalum nitride or any combination thereof. For example, the lining layer 120 may be composed of TiN. The lining layer 120 conformally covers the bottom surface 102a and the sidewalls 102b of the recessed trench 102.

As shown in FIG. 2B, an upper portion of the lining layer 120 is removed from the recessed trench 102. The upper portion of insulating layer 110 within the sidewall 102b and the pad layer 230 outside the recessed trench 102 are exposed. At this point, the lining layer 120 comprises a horizontal segment 1 20a at the bottom surface 102a and vertical segments 120b at the sidewalls 102b. To remove the upper portion of the lining layer 120, a photoresist layer or a sacrificial layer may be deposit to fill the recessed trench 102 and then etched back to a predetermined depth. The exposed upper portion of the lining layer 120 is then etched away. The remanent photoresist layer is then removed from the recessed trench 102. After the removal of the upper portion of the lining layer 120, a cleaning process may be carried out to clean the surface of the semiconductor substrate 100. For example, the surface of the semiconductor substrate 100 may be cleaned with a cleaning solution comprising HF or H3PO4.

As shown in FIG. 2C, after the cleaning process, a selective tungsten deposition process is carried out to selectively deposit a tungsten layer 320 on the horizontal segment 120a and the vertical segments 120b of the lining layer 120. The tungsten substantially does not deposit on the exposed upper portion of insulating layer 110 within the sidewall 102b and the exposed pad layer 230 outside the recessed trench 102. By way of example, to selectively deposit the tungsten layer 320 on the lining layer 120, in a first stage, a reaction gas comprising tungsten hexafluoride (WF6) may be employed to react with the TiN, thereby forming W seed layer thereon. In a second stage, hydrogen (H2) and WF6 gases are supplied to selectively grow W layer on the lining layer 120 in a relatively higher growth rate.

It is advantageous to use the present invention because the majority of the lining layer 120 is removed prior to the selective W deposition. Only the specific W binding sites are preserved at the bottom the recessed trench 102. By doing this, the stress is significantly reduced and the word line bending or deformation is avoided.

Those skilled in the art will readily observe that numerous modifications and alterations of the device and method may be made while retaining the teachings of the invention. Accordingly, the above disclosure should be construed as limited only by the metes and bounds of the appended claims.

1-10. (canceled)

11. A buried word line, comprising:
a substrate having thereon a recessed trench comprising a bottom surface and a sidewall;
an insulating layer on the bottom surface and the sidewall;
a lining layer covering the bottom surface and a lower portion of the sidewall in the recessed trench, wherein the lining layer has a cleaned surface that is cleaned by a cleaning solution comprising HF or H3PO4; and
a tungsten layer selectively deposited on the cleaned surface of the lining layer.

12. The buried word line according to claim 11 wherein the lining layer is a TiN layer.

13. The buried word line according to claim 11 wherein an upper portion of the sidewall is not covered by the lining layer.

14. The buried word line according to claim 13 wherein the tungsten layer is not deposited on the upper portion.
